(19) United States
(12) Patent Application Publication
(10) Pub. No.: US 2013/0230937 A1
(43) Pub. Date: Sep. 5, 2013

(54) METHOD FOR MANUFACTURING PERPENDICULAR LED

(71) Applicants: Hyun-Woo Shin, Gwacheon-Si (KR); Kyo-Sun Ku, Suwon-Si (KR); Byung-Du Oh, Seoul (KR)

(72) Inventors: Hyun-Woo Shin, Gwacheon-Si (KR); Kyo-Sun Ku, Suwon-Si (KR); Byung-Du Oh, Seoul (KR)

(73) Assignee: HANBEAM CO., LTD., Suwon-Si ,Gyeonggi-Do (KR)

(21) Appl. No.: 13/988,325

(22) PCT Filed: May 25, 2011
(86) PCT No.: PCT/KR2011/003822

§ 371 Date: May 17, 2013

(30) Foreign Application Priority Data
Nov. 18, 2010 (KR) 10-2010-0115074

(51) Int. Cl. H01L 33/00

(52) U.S. Cl. CPC H01L 33/005
USPC 438/46

(57) ABSTRACT

A method for manufacturing a perpendicular LED for preventing bending of a wafer while reducing the time required for manufacturing to improve the mass production yield of perpendicular LEDs includes: growing an LED compound semiconductor structure on a sapphire substrate; forming an adhesive layer which is stacked on the LED compound semiconductor structure in the order of a first solder layer, a heat-emitting layer, and a second solder layer; forming a conductive substrate on the adhesive layer; coupling the first solder layer and the second solder layer by means of the heat which is generated from reacting the heat-emitting layer; and removing the sapphire substrate.

### TECHNICAL FIELD

The present invention relates to a method of manufacturing a vertical type LED, and more particularly, to a method of manufacturing vertical type LED which includes a conductive-substrate bonding process and is capable of preventing wafer warpage.

### BACKGROUND ART

Light emitting diodes (LEDs) are semiconductor devices for emitting light on the basis of recombination of electrons and holes. Since LEDs consume small amounts of electricity and are efficient, LEDs tend to be widely used as various light sources in optical communication devices and electronic devices.

These LEDs can be classified into a horizontal type and a vertical type according to differences in electric current direction and structure. Of them, horizontal type LEDs have been widely used for low or medium output power. Recently, it has been made an attempt to use horizontal type LEDs for high output power. However, due to a serious heat problem, no progress has been made in mass production. In contrast, vertical type LEDs have optimal structures for high output power, and are excellent in heat release properties. However, it is time to need to improve the yield of mass production even with respect to vertical type LEDs.

FIG. 1 is a vertical cross-sectional view of vertical type LED for explaining a method of manufacturing vertical type LED according to the related art.

A general method of manufacturing vertical type LED includes a process of forming an electrically conductive substrate 500 with electric conductivity, such as a metal substrate or a Si substrate, on a surface of an epitaxial wafer formed by growing a compound semiconductor structure on a sapphire substrate or the like, and removing the sapphire substrate (not shown). As a method of peeling off the sapphire substrate, a laser lift off (hereinafter, referred to as “LLO”) method or the like can be used.

Meanwhile, as the method of forming the electrically conductive substrate 500 on the epitaxial wafer according to the related art, there is the conventional wafer bonding method. In this method, bonding is conducted at a high temperature, followed by cooling to room temperature. Due to the difference in thermal expansion coefficient between the electrically conductive substrate and the sapphire substrate of the epitaxial wafer, a warping phenomenon occurs in an intermediate product which is in a state in which bonding has finished. This phenomenon causes problems when the sapphire substrate is removed by an LLO process.

In other words, since the thermal expansion coefficient of the electrically conductive substrate is much smaller than the thermal expansion coefficient of the sapphire substrate, after bonding is conducted at a high temperature, in progress of cooling, the electrically conductive substrate contracts less, whereas the sapphire substrate of the epitaxial wafer contracts more, such that high tensile force is applied to the sapphire substrate. As a result, the warping phenomenon occurs in the intermediate product obtained by bonding the electrically conductive substrate and the epitaxial wafer. If this phenomenon occurs, in the course of removing the sapphire substrate by the LLO process, optical alignment for applying uniform laser power is difficult. Therefore, the LLO process and the subsequent processes such as a photolithographic patterning process and an n-metal process may become impossible.

As another method of forming the electrically conductive substrate 500 on the surface of the epitaxial wafer according to the related art, there is a method of directly applying a metal layer as the electrically conductive substrate 500 on the surface of the epitaxial wafer by electroplating. However, even in this method, due to a residual stress generated after the LLO process, the intermediate product having been subjected to deposition seriously warps. FIG. 2 shows the wafer warping phenomenon occurring in the intermediate product after the process of directly forming the electrically conductive substrate 500 on the epitaxial wafer by electroplating and removing the sapphire substrate through the LLO process, and due to this warping phenomenon, the subsequent processes such as a photolithographic patterning process and an n-metal process may become impossible.

### DISCLOSURE

### Technical Problem

The present invention was made to solve the above-mentioned problem, and an object of the present invention is to provide a method of manufacturing vertical type LED which prevents wafer warpage, which results in improving mass production yield of vertical type LED. In addition, the manufacturing throughput is improved significantly by reducing the bonding process time compared with the conventional bonding.

### Technical Solution

In order to achieve the above-mentioned objects, a method of manufacturing vertical type LED according to the present invention includes a process of growing an LED compound semiconductor structure on a sapphire substrate, a process of forming a bonding layer by sequentially forming a first solder layer, a heat generating layer, and a second solder layer on the LED compound semiconductor structure, a process of forming an electrically conductive substrate on the bonding layer, a process of bonding the first solder layer and the second solder layer by heat generated by making the heat generating layer react, and a process of removing the sapphire substrate.

In the above-mentioned configuration, the heat generating layer may be formed by mixing the respective powders of two components forming any one combination among combinations of Al and Ni (Al/Ni), Al and Ti (Al/Ti), Ni and Si (Ni/Si), Nb and Si (Nb/Si), and Al and Monel (Al/Monel), or may be formed in a multi-layered thin film structure by alternately stacking layers of the two components. The multi-layered thin film structure may be formed in a separable foil form, or may be deposited directly on the first solder layer. In case of a separable foil, in order to prevent oxidation of the surfaces of thin metal films, oxidation preventing layers may be formed of a low-melting-point material such as AgSn, AuSn, or InCuAg on both surfaces of the foil.

The heat generating layer may be formed in the multi-layered thin film structure by alternately stacking foil-like thin films or alternately forming thin films by vapor deposition process.

The heat generating layer may generate heat by Self-propagating High-temperature Synthesis.

### Advantageous Effects

According to the method of manufacturing vertical type LED on the basis of the present invention, it is possible to prevent wafer warpage resulting in improving the yield of mass production of vertical type LED. In addition, the manufacturing throughput is improved by reducing the bonding time compared with the conventional bonding performed at high temperature followed by slow cooling to room temperature.

### DESCRIPTION OF DRAWINGS

FIG. 1 is a vertical cross-sectional view of vertical type LED manufactured by a method of manufacturing vertical type LED according to the related art.

FIG. 2 is a picture showing a wafer warping phenomenon according to an electroplating method included in the related art.

FIG. 3 is a step flow chart according to an embodiment of a method of manufacturing vertical type LED according to the present invention.

FIG. 4 is a vertical cross-sectional view of vertical type LED manufactured by the method of manufacturing vertical type LED according to the embodiment of the present invention.

FIGS. 5a to 5e are vertical cross-sectional views for explaining each step of the method of manufacturing the vertical type LED shown in FIG. 4.

FIG. 6 is an enlarged vertical cross-sectional view illustrating only some layers of a heat generating layer shown in FIG. 4.

FIG. 7 is a vertical cross-sectional view illustrating a form in which the heat generating layer is ignited and reaction propagates.

FIG. 8 is a vertical cross-sectional view illustrating a bonding layer in which the reaction caused by the heat generating layer has been terminated.

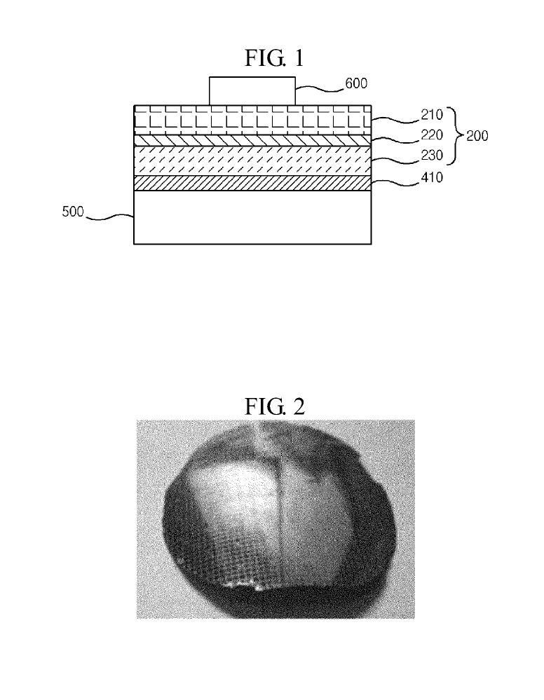

### BEST MODE

Hereinafter, an embodiment of a method of manufacturing vertical type LED according to the present invention will be described in detail with reference to the accompanying drawings.

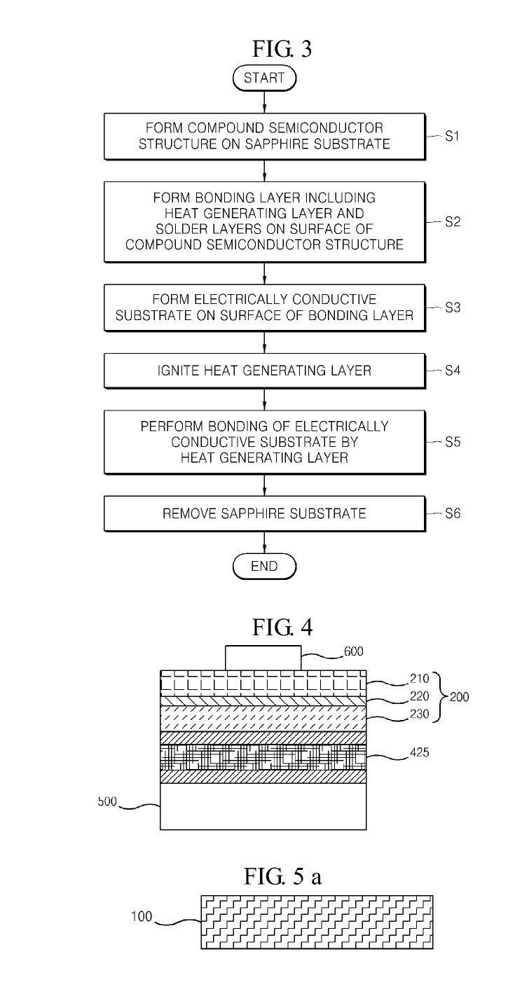

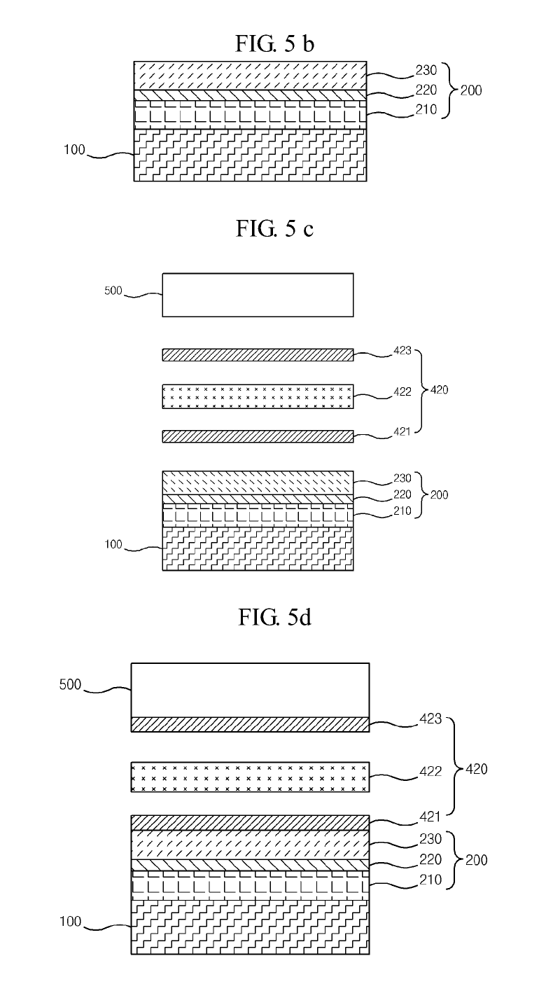

FIG. 3 is a step flow chart for explaining a method of manufacturing vertical type LED according to an embodiment of the present invention, and FIG. 4 is a vertical cross-sectional view of vertical type LED manufactured by the method of manufacturing vertical type LED according to the embodiment of the present invention, and FIGS. 5a to 5e are vertical cross-sectional views for explaining each step of the method of manufacturing vertical type LED shown FIG. 3. As shown in FIGS. 3 to 5, in manufacturing vertical type LED according to the present invention, first, in STEP S1, on a substrate, for example, a sapphire substrate 100 as shown in FIG. 5a, a compound semiconductor structure 200 as shown in FIG. 5b is formed.

This compound semiconductor structure 200 is a light emitting device which is formed by stacking an n-type compound semiconductor layer 210, an active layer 220, and a p-type compound semiconductor layer 230 in this order on the sapphire substrate 100 serving as a substrate for growth, and converts an electric signal into an optical signal.

If an electric field is applied, in the active layer 220, electrons injected from the n-type compound semiconductor layer 210 and holes injected from the p-type compound semiconductor layer 230 are combined, whereby light is emitted.

Subsequently, in addition to the compound semiconductor structure 200, a functional layer such as a reflective layer for reflecting light generated in the active layer 220 to emit the light to the outside, or a contact layer for forming ohmic contact with the n-type compound semiconductor layer 210 or the p-type compound semiconductor layer 230 may be formed. This functional layer functions to reflect incident light coming from the compound semiconductor structure 200 upward or form ohmic contacts between the compound semiconductor layers and electrodes, thereby increasing the intensity of the light emitting device; however, it is not an essential element of the present invention.

Next, in STEPS S2 and S3, as shown in FIGS. 5c and 5d, on the compound semiconductor structure 200, a bonding layer 420 and an electrically conductive substrate 500, for example, a metal substrate or a Si substrate are bonded. Here, the bonding layer 420 functions to bond the electrically conductive substrate 500 and the compound semiconductor structure 200, and is formed by subsequently stacking a first solder layer 421, a heat generating layer 422, and a second solder layer 423 as independent layers as shown in FIG. 5c.

Alternatively, as shown in FIG. 5d, the first solder layer 421 is formed on the compound semiconductor structure 200, and the second solder layer 423 is formed a first surface of the electrically conductive substrate 500, and the heat generating layer 422 is formed on the first solder layer 421 or the second solder layer 423. Next, the first solder layer 421, the heat generating layer 422, and the second solder layer 423 are sequentially stacked, whereby the bonding layer is formed.

Next, in STEPS S4 and S5, the heat generating layer 422 is ignited, whereby the electrically conductive substrate 500 and the compound semiconductor structure 200 are bonded.

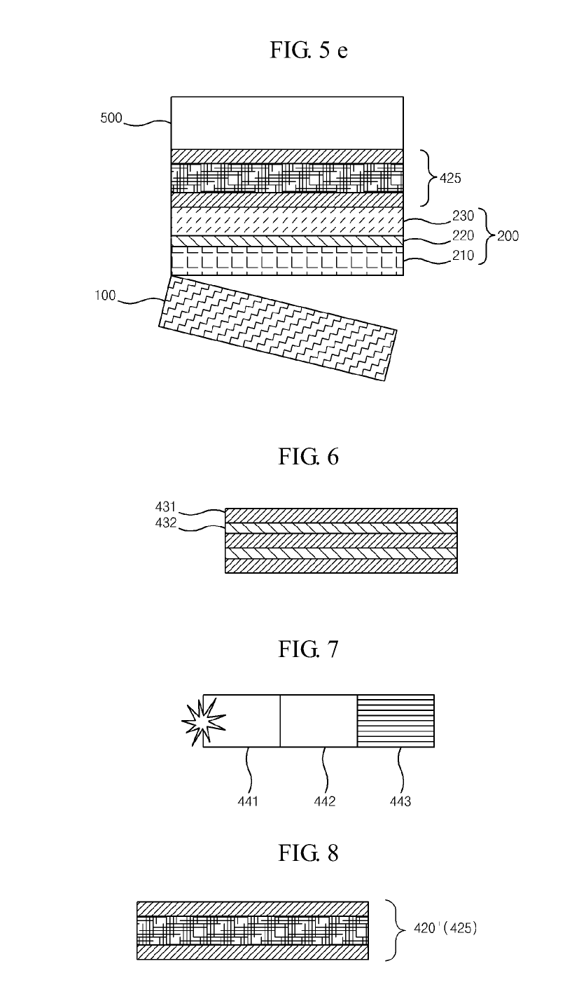

FIG. 6 is an enlarged vertical cross-sectional view illustrating only some layers of a part of the heat generating layer 422 shown in FIG. 4, and shows some layers of the heat generating layer 422 formed in a multi-layered thin film structure by alternately stacking, for example, thin Al films 431 and thin Ni films 432 having thicknesses in nano-scale. As shown in FIG. 6, the heat generating layer 422 is formed in a multi-layered thin film structure by alternately stacking thin films composed of two components forming any one combination among combinations of Al and Ni (Al/Ni), Al and Ti (Al/Ti), Ni and Si (Ni/Si), Nb and Si (Nb/Si), and Al and Monel (Al/Monel) (which is an alloy containing Ni and Cu in a ratio of 7:3) and having thicknesses in nano-scale, several hundreds to several thousands of times. The above-mentioned multi-layered thin film structure may be formed in a separable foil form or may be deposited directly on the first solder layer 421 or the second solder layer 423 serving as a base structure. At this time, in case of depositing the multi-layered thin film structure directly on the base structure, if the deposition is performed in an in-situ way, an aligning process and the like can be omitted.

As another embodiment, the heat generating layer 422 may be formed by mixing the respective powders of two components forming any one of the above-mentioned combinations.

Then, in order to prevent oxidation of metal surfaces of the multi-layered thin film structure or the power form constituting the heat generating layer 422, oxidation preventing layers may be formed of a low-melting-point material such as AgSn, AuSn, and InCuAg on both surfaces of the heat generating layer 422. At this time, in a case of a separable foil, it is further preferable to form oxidation preventing layers on the surfaces, thereby increasing stability.

FIG. 7 is a vertical cross-sectional view illustrating a form in which the heat generating layer 422 is ignited and reaction propagates. As shown in FIG. 7, as a scheme of igniting the heat generating layer 422, Self-propagating High-temperature Synthesis (SHS) can be used. According to the SHS, if an ignition source having low energy in an electric, optical or thermal form is locally applied to the heat generating layer 422, the reaction starts. If the reaction starts, taking advantage of the start of the reaction, the temperature rapidly rises in a very short time, and a large amount of energy is generated. Therefore, the reaction self-propagates. More specifically, the propagation speed of the above-mentioned reaction depends on the layer thickness, and can increase up to about 30 m/s, and the temperature of local heat attributable to the reaction can reach more than 1200° C. in several milliseconds. Further, when high-temperature energy generated by the reaction of the heat generating layer 422 is transferred to the first solder layer 421 and the second solder layer 423, since the energy is accurately and locally transferred without being dispersed, the electrically conductive substrate 500 and the sapphire substrate 100 are not thermally damaged, and the wafer warping phenomenon which occurs according to thermal expansion coefficients in the related art does not occur. Furthermore, this process method has advantages in which any furnace is unnecessary, and it is unnecessary to separately provide an external heat source as in the conventional bonding.

Meanwhile, since the amount of heat generation of the heat generating layer 422 is determined by the mass of the heat generating layer, the heat generating layer needs to a weight or thickness sufficient for ensuring an amount of heat generation necessary to bond the first solder layer 421 and the second solder layer 423. The total thickness of the first and second solder layers can be selected in a range of 0.5 μm to 10 μm, and the thickness of the heat generating layer can be selected in a range of 10 μm to 100 μm. It is preferable that the ratio of the thickness of the heat generating layer relative to the total thickness of the first and second solder layers should be between 1:5 and 1:20. It is not preferable that the heat generating layer has an inappropriate thickness. The reason is that the following problems may occur. If the thickness of the heat generating layer is relatively too thin, since the amount of heat generation is not sufficient, the bonding of the first and second solder layers is not perfect. Meanwhile, if the thickness of the heat generating layer is relatively too thick, since the amount of heat generation is too large, heat is transferred even to the electrically conductive substrate 500 and the sapphire substrate 100. Therefore, it is more likely that the electrically conductive substrate and the sapphire substrate may be thermally damaged or the warping phenomenon may occur. Even though thermal damage may not occur, a thermal resistive layer may be formed, which results in that the heat generated in the compound semiconductor structure 200 may not be easily transferred to the electrically conductive substrate side 500.

FIG. 7 shows a portion 441 in which ignition has stated and the reaction has terminated, a portion 442 which has received energy and the reaction is in progress, and a portion 443 in which the reaction does not start yet.

FIG. 8 is a vertical cross-sectional view illustrating a bonding layer 425 in which the reaction caused by the heat generating layer has terminated. If the above-mentioned reaction of the heat generating layer terminates, the first solder layer 421 and the second solder layer 423 of the bonding layer become completely bonded states.

Next, in STEP S6 of FIG. 3, as shown in FIG. 5e, the sapphire substrate 100 is removed from the compound semiconductor structure 200. As a result, an intermediate product in which the bonding layer 425 and the compound semiconductor structure 200 have been sequentially stacked on the electrically conductive substrate 500 is obtained. As shown in FIG. 4, on that intermediate product, a contact electrode 600 is formed, whereby it is possible to provide electricity to a vertical type LED.

The method of manufacturing vertical type LED according to the present invention is not limited to the above-mentioned embodiment, and can be modified in various forms in the technical scope of the present invention.

1. A method of manufacturing a vertical type LED, comprising;
growing an LED compound semiconductor structure (200) on a sapphire substrate;
forming a bonding layer (420) by sequentially stacking a first solder layer (421), a heat generating layer (422), and a second solder layer (423) on the LED compound semiconductor structure;
forming an electrically conductive substrate on the bonding layer;
bonding the first solder layer (421) and the second solder layer (423) by heat generated by making the heat generating layer react; and
removing the sapphire substrate.

2. A method of manufacturing a vertical type LED, comprising;
growing an LED compound semiconductor structure (200) on a sapphire substrate;
forming a first solder layer (421) on the LED compound semiconductor structure;
forming a second solder layer (423) on a first surface of an electrically conductive substrate;
forming a heat generating layer (422) on the first solder layer (421) or the second solder layer (423);
bonding the first solder layer (421) and the second solder layer (423) by heat generated by making the heat generating layer react; and
removing the sapphire substrate.

3. The method of manufacturing vertical type LED according to claim 1, wherein:
the heat generating layer is formed in a foil form having a multi-layered thin film structure by alternately stacking the respective layers of two components forming any one combination among combinations of Al and Ni (Al/Ni), Al and Ti (Al/Ti), Ni and Si (Ni/Si), Nb and Si (Nb/Si), and Al and Monel (Al/Monel).

4. The method of manufacturing vertical type LED according to claim 1, wherein:
the heat generating layer is formed in the form of a multi-layered thin film structure by alternately depositing the respective layers of two components forming any one combination among combinations of Al and Ni (Al/Ni), Al and Ti (Al/Ti), Ni and Si (Ni/Si), Nb and Si (Nb/Si), and Al and Monel (Al/Monel) directly on the first solder layer (421) or the second solder layer (423).

5. The method of manufacturing vertical type LED according to claim 1, wherein:
the heat generating layer is formed in the form of a multi-layered thin film structure by alternately depositing the respective layers of two components forming any one combination among combinations of Al and Ni (Al/Ni), Al and Ti (Al/Ti), Ni and Si (Ni/Si), Nb and Si (Nb/Si), and Al and Monel (Al/Monel) directly on the compound semiconductor structure (200) or the electrically conductive substrate (500).

6. The method of manufacturing vertical type LED according to claim 1, wherein:
the heat generating layer is formed by mixing the respective powders of two components forming any one combination among combinations of Al and Ni (Al/Ni), Al and Ti (Al/Ti), Ni and Si (Ni/Si), Nb and Si (Nb/Si), and Al and Monel (Al/Monel).

7. The method of manufacturing vertical type LED according to claim 1, wherein:
the heat generating layer generates heat by Self-propagating High-temperature Synthesis.

8. The method of manufacturing vertical type LED according to claim 1, wherein:
the reaction of the heat generating layer is ignited by an electric, optical, or thermal energy source.

9. The method of manufacturing vertical type LED according to claim 2, wherein:
the heat generating layer is formed in a foil form having a multi-layered thin film structure by alternately stacking the respective layers of two components forming any one combination among combinations of Al and Ni (Al/Ni), Al and Ti (Al/Ti), Ni and Si (Ni/Si), Nb and Si (Nb/Si), and Al and Monel (Al/Monel).

10. The method of manufacturing vertical type LED according to claim 2, wherein:
the heat generating layer is formed in the form of a multi-layered thin film structure by alternately depositing the respective layers of two components forming any one combination among combinations of Al and Ni (Al/Ni), Al and Ti (Al/Ti), Ni and Si (Ni/Si), Nb and Si (Nb/Si), and Al and Monel (Al/Monel) directly on the first solder layer (421) or the second solder layer (423).

11. The method of manufacturing vertical type LED according to claim 2, wherein:
the heat generating layer is formed in the form of a multi-layered thin film structure by alternately depositing the respective layers of two components forming any one combination among combinations of Al and Ni (Al/Ni), Al and Ti (Al/Ti), Ni and Si (Ni/Si), Nb and Si (Nb/Si), and Al and Monel (Al/Monel) directly on the compound semiconductor structure (200) or the electrically conductive substrate (500).

12. The method of manufacturing vertical type LED according to claim 2, wherein:
the heat generating layer is formed by mixing the respective powders of two components forming any one combination among combinations of Al and Ni (Al/Ni), Al and Ti (Al/Ti), Ni and Si (Ni/Si), Nb and Si (Nb/Si), and Al and Monel (Al/Monel).

13. The method of manufacturing vertical type LED according to claim 2, wherein:
the heat generating layer generates heat by Self-propagating High-temperature Synthesis.

14. The method of manufacturing vertical type LED according to claim 2, wherein:
the reaction of the heat generating layer is ignited by an electric, optical, or thermal energy source.
